(19) United States
(12) Patent Application Publication
(10) Pub. No.: US 2015/0228371 A1
(43) Pub. Date: Aug. 13, 2015

(54) METHOD FOR PRODUCING ELECTRICALLY CONDUCTIVE THIN FILM, AND ELECTRICALLY CONDUCTIVE THIN FILM PRODUCED BY SAID METHOD

(71) Applicant: NATIONAL INSTITUTE OF ADVANCED INDUSTRIAL SCIENCE AND TECHNOLOGY, Tokyo (JP)

(72) Inventors: Yeji Kim, Tsukuba-shi (JP); Masayuki Chikamatsu, Tsukuba-shi (JP); Reiko Azumi, Tsukuba-shi (JP); Takeshi Saito, Tsukuba-shi (JP); Nobutsugu Minami, Tsukuba-shi (JP)

(73) Assignee: NATIONAL INSTITUTE OF ADVANCED INDUSTRIAL SCIENCE AND TECHMOLOGY, Tokyo (JP)

(21) Appl. No.: 14/418,143

(22) PCT Filed: Jul. 30, 2013
(86) PCT No.: PCT/JP2013/070654

§ 371 Date: Jan. 29, 2015

(30) Foreign Application Priority Data
Jul. 30, 2012 (JP) 2012-168951

(51) Int. Cl. H01B 1/24; H05K 1/03; H05K 1/02; B29C 71/00; H01B 3/30

(52) U.S. Cl. CPC H01B 1/24; B29C 71/0009; H01B 3/30; H05K 1/0274; H05K 1/032; B29C 2071/0027; B29K 2103/04

(57) ABSTRACT

The purpose of the present invention is to provide a carbon nanotube thin film in which carbon nanotubes exist in a uniformly dispersed state, the thickness and light transmittance of the film can be adjusted easily and are uniform, and high electrical conductivity or high semiconductor properties can be achieved. Carbon nanotubes are mixed with an electrically-non-conductive matrix capable of dispersing the carbon nanotubes satisfactorily therein, such as hydroxypropyl cellulose, to prepare a dense ink that is dispersed in a solvent, the ink is prepared into a film having a uniform thickness employing a doctor blade method or a screen printing method, and subsequently the electrically-non-conductive matrix is removed with a solvent or by a photonic curing method or an oxygen plasma treatment. In this manner, a thin film in which the electrical conductivity or semiconductor properties inherent in carbon nanotubes are recovered can be produced.

### TECHNICAL FIELD

The present invention relates to a method for producing an electrically conductive thin film, in particular a method for producing an electrically conductive thin film by removing an electrically-non-conductive matrix from a carbon nanotube-containing thin film in which carbon nanotubes are dispersed in a state of being separated from each other in the electrically-non-conductive matrix, and relates to an electrically conductive thin film obtained by the method.

### BACKGROUND ART

Carbon nanotubes have attracted enormous attention as new materials capable of achieving various new functions and intensive researches and developments have been conducted worldwide. In order to use carbon nanotubes effectively in various industrial applications in future, an indispensable problem is that carbon nanotubes should be formed into a uniform thin film. In addition, when this thin film is used as an optical component, it is necessary that the tubes are separated from each other (see NPL 1).

Thus, the present inventors conducted intensive research concerning the method for forming the tubes separated from each other into a uniform thin film, and proposed a carbon nanotube-containing thin film in which carbon nanotubes are dispersed in a state of being separated from each other using matrix polymers made from gelatin or cellulose derivatives (PTL1).

With regard to this film, a uniform carbon nanotube-containing thin film can be obtained either by mixing carbon nanotubes directly with the polymers or by dispersing carbon nanotubes with a surfactant and then mixing them with the polymers. In addition, when single-wall carbon nanotubes (hereinafter, sometimes referred to as SWNTs) are used, a luminescence peak in the near-infrared region, which is a characteristic of SWNTs separated from each other, can be observed.

In order that a carbon nanotube-containing thin film can have the high electrical conductivity or the high semiconductor properties of carbon nanotubes, it is necessary that the mixture in the thin film does not prevent the electrical properties. In the above method, however, it is difficult to apply a sufficient electric current to the thin film because the matrix polymer is an electrical insulator. Thus, it has been difficult so far to produce an electrically conductive thin film, a transparent electrode or the like having satisfactory properties using the thin films.

For this reason, a method in which such a thin film is cured by heating after the production of the thin film to decompose and remove the electrically-non-conductive matrix is known (NPL 2).

However, this method has a problem in treating a thin film of a rolled sheet type in order because it is necessary to place the thin film in a high-temperature furnace. In addition, there is a problem that substrates which may soften or decompose at a high temperature, such as a plastic substrate, cannot be used, because the thin film is heated at a high temperature.

In addition, in order to improve the electrical conductivity of a carbon nanotube-containing thin film, it was proposed to use electrically conductive polymers such as soluble substituted poly(phenylene vinylene)s or copolymers thereof, or soluble substituted polythiophenes as the matrix polymer (PTL 2).

However, the high electrical conductivity or the high semiconductor properties inherent in carbon nanotubes are not exhibited because the electrical conductivity or the semiconductor properties of the film are determined by the electrical properties of the electrically conductive polymers. That is, it is obvious that the electronic function inherent in carbon nanotubes cannot be fully used with such a thin film.

Thus, it was also proposed to dope the dispersant contained in the thin film by using a dopant solution (PTL 3). However, the electrical conductivity of an electrically conductive polymer is inferior to the electronic function of carbon nanotubes even if the polymer is doped, and hence the electrical conductivity of the whole film is determined by the inferior electrical properties of the electrically conductive polymer. Thus, it is not possible to secure a satisfactory electrical conductivity. In addition, a step for immersing in the dopant solution, a step for rinsing out the residual dopant and a step for drying the rinsed carbon nanotube-containing thin film are necessary.

It was reported that, in single-wall carbon nanotubes, metallic ones (called m-SWNTs here) and semiconducting ones (called s-SWNTs here) are inevitably mixed during the synthesis thereof, and thus there is a limit to the compatibility of the electrical conductivity with the light transmittance of the thin film.

Therefore, it was proposed to form a thin film by dispersing single-wall carbon nanotubes, in which m-SWNTs and s-SWNTs are mixed, in an amine solution using the amine as the dispersant, subjecting the obtained dispersion to centrifugal separation or filtration to separate/concentrate the m-SWNTs, and coating the obtained dispersion containing the m-SWNTs on a substrate using an airbrush or the like (PTL 4). It is said that, according to this method, the electrical conductivity can be improved using metallic carbon nanotubes only, with containing substantially no polymer dispersant or polymers such as a binder.

However, although this method requires a step for separating/concentrating the metallic carbon nanotubes in order to remove the semiconducting nanotubes having a low electrical conductivity, the sheet resistance achieved is about 4, 800 Ω/sq (transmittance of 96.1%), which is higher than the sheet resistance of the electrically conductive film of the invention, which is produced from all the nanotubes without separation/concentration.

As described in PTL 4, this is considered to be because the layers are dried in order of spraying when the film is formed by an airbrush method on a PET substrate being heated at 85° C. on a hot plate and it is thus extremely difficult to obtain a uniform thin film without unevenness. In addition, when an industrial electrode with a large area is produced, it is further difficult to regulate the thickness over a large area and this means that the regulation of the sheet resistance is difficult. Furthermore, although the amine as the dispersant is easily removed completely by heating and rinsing, this is disadvantageous for the adherence to the substrate. Therefore, this method is not suitable for a flexible device, which requires bendability.

### CITATION LIST

### Patent Literature

PTL 1: WO2005/082775

PTL 2: JP-A-2006-265035

PTL 3: JP-A-2008-103329

PTL 4: WO2009/008486

### Non Patent Literature

NPL 1: Band gap fluorescence from individual single-walled carbonnanotubes, Science, vol. 297, pp 593-596 (2002), Jul. 26, 2002

NPL 2: Highly sensitive, room-temperature gas sensors prepared from cellulose derivative assisted dispersions of single-wall carbon nanotubes, Japanese Journal of Applied Physics, vol. 47, pp 7440-7443 (2008), Sep. 12, 2008

### SUMMARY OF INVENTION

### Technical Problem

As described above, when it becomes possible to form carbon nanotubes into a uniform thin film with a large area at a time on a flexible substrate, for example plastic, by an easy method and apply a sufficient electric current to the thin film, the thin film will be able to be used for transparent electrodes of touch screens and the like, electrodes of organic EL and organic solar cells and the like utilizing the flexibility of carbon nanotubes and the industrial utility value thereof is great. However, a thin film meeting such demand has not been developed so far.

The invention was made in view of the above circumstances and aims to provide a method for producing an electrically conductive thin film in which carbon nanotubes exist in a uniformly dispersed state and the thickness and the light transmittance are uniform and which has a high electrical conductivity and to provide a thus produced electrically conductive thin film. Furthermore, another object of the invention is to provide a method in which the thickness, the transmittance and the electrical conductivity can be easily adjusted as required and a uniform thin film with a large area can be formed at a time directly on a flexible substrate, for example plastic, without steps for transferring and the like. Moreover, the invention also aims to provide a production method: in which commercially available nanotubes can be directly used without separating or concentrating the nanotubes as the main material; which minimizes waste of materials, which is caused to a considerable extent in known spray methods and spin coating methods due to the accumulation of the nanotubes on parts other than the substrate; and which is excellent in the cost-effectiveness in terms of materials, environment and energy, unlike the film-formation methods with high energy consumption such as vacuum vapor deposition and thermal CVD.

### Solution to Problem

The inventors have conducted intensive studies to achieve the above objects, and as a result made it possible to form a carbon nanotube-containing thin film employing a doctor blade method, a screen printing method or the like, by dispersing carbon nanotubes in a state of being separated from each other using a cellulose derivative as a dispersant and adjusting the concentration of the nanotubes, the viscosity of the dispersion solution, the dispersion solvent, the hydrophobicity of the substrate and the like. It was found that, by subsequently removing an electrically-non-conductive matrix consisting of the cellulose polymer by a particular method, the electrical conductivity or the semiconductor properties inherent in carbon nanotubes (hereinafter, the term “electrical conductivity” is used to indicate these properties together) are recovered and thus an electrically conductive thin film with a high electrical conductivity can be obtained. It was further found that the particular method is one of a solution treatment using a poor solvent, an atmospheric-pressure plasma method and a photonic curing method, and that an electrically conductive thin film in which the nanotubes are individually dispersed without causing the film disintegration or aggregation can be obtained by one of the methods or more than one of the methods in combination depending on the use and the substrate.

The invention was completed based on the findings and the following inventions are provided according to the invention.

[1] A method for producing an electrically conductive thin film by removing an electrically-non-conductive matrix consisting of a cellulose derivative from a carbon nanotube-containing thin film in which carbon nanotubes are dispersed in a state of being separated from each other in the electrically-non-conductive matrix,

wherein the electrically-non-conductive matrix is removed by treating the carbon nanotube-containing thin film with a poor solvent.

[2] A method for producing an electrically conductive thin film, wherein the poor solvent is 2-propanol.

[3] A method for producing an electrically conductive thin film by removing an electrically-non-conductive matrix consisting of a cellulose derivative from a carbon nanotube-containing thin film in which carbon nanotubes are dispersed in a state of being separated from each other in the electrically-non-conductive matrix,

wherein the electrically-non-conductive matrix is removed by photonically curing the carbon nanotube-containing thin film.

[4] A method for producing an electrically conductive thin film by removing an electrically-non-conductive matrix consisting of a cellulose derivative from a carbon nanotube-containing thin film in which carbon nanotubes are dispersed in a state of being separated from each other in the electrically-non-conductive matrix,

wherein the electrically-non-conductive matrix is decomposed and removed by applying oxygen plasma to the carbon nanotube-containing thin film.

[5] The method for producing an electrically conductive thin film according to any one of [1] to [4], wherein the cellulose derivative is hydroxypropyl cellulose.

[6] The method for producing an electrically conductive thin film according to any one of [1] to [5], wherein two or more of the methods described in [1], [3] and [4] are combined.

[7] The method for producing an electrically conductive thin film according to any one of [1] to [6], wherein the electrically-non-conductive matrix is removed from the carbon nanotube-containing thin film except for a part thereof.

[8] The method for producing an electrically conductive thin film according to any one of [1] to [7], wherein the carbon nanotube-containing thin film is a thin film formed by a doctor blade method or a screen printing method.

[9] An electrically conductive thin film which is produced by the method described in any one of [1] to [8].

[10] The electrically conductive thin film according to [9] which is formed on a substrate consisting of a plastic film having a softening point or a decomposition point lower than 300° C.

[11] A transparent electrode which has the electrically conductive thin film according to [9] on a transparent substrate.

[12] The transparent electrode according to [11], wherein the transparent substrate is a plastic film having a softening point or a decomposition point lower than 300° C.

### Advantageous Effects of Invention

The invention has the following excellent effects: a carbon nanotube-containing thin film can be produced easily by a doctor blade method, a screen printing method or the like, with carbon nanotubes existing in a uniformly dispersed state; the thickness and the light transmittance can be adjusted easily; and the high electrical conductivity or the high semiconductor properties inherent in carbon nanotubes can be sufficiently exhibited by removing the dispersant. Accordingly, it is easy to form electrically conductive thin films varying from one having a transmittance of 99% to an opaque one depending on the use and the thin film can be used for applications varying from a transparent electrically conductive film to a conductive wire which requires a high electrical conductivity. Moreover, with regard to the carbon nanotube-containing thin film obtained in the invention, the change in the sheet resistance after doping by immersion in a concentrated nitric acid solution is very small. Furthermore, in the invention, by using carbon nanotubes having semiconductor properties, applications to a channel layer of a thin film transistor or the like are also possible.

In addition, types of the substrate are not limited and the thin film can be freely formed on substrates varying from glass to a flexible substrate and paper. It becomes possible to use the thin film for transparent electrodes of touch screens and the like, electrodes of organic EL and organic solar cells and the like utilizing the flexibility of carbon nanotubes, because the thin film can be formed uniformly with a large area at a time on a flexible substrate, for example plastic. Furthermore, according to the method of the invention, the adherence of the nanotubes to the substrate is excellent and the surface sheet resistance caused by peeling from the substrate can be prevented from increasing because the electrically-non--conductive matrix can be partially removed. If necessary, it is also possible to regulate the flexibility, the strength and the like of the electrically conductive thin film because of the partial removal of the matrix. In fact, when carbon nanotube electrically conductive thin films formed on a flexible substrate were subjected to a bendability test, the initial properties were maintained even after conducting the bending test for 200,000 times.

Furthermore, for the formation of the carbon nanotube-containing thin film employing a doctor blade method or the like according to the invention, commercially available carbon nanotubes can be used. It is a process in which the consumption of materials is reduced and energy is saved during the production of the electrically conductive thin film, and an electrically conductive thin film with a transmittance meeting the requirement can be formed by roll-to-roll processing, because an expensive vacuum apparatus or a sputtering step is not used. Thus, it is suitable for the scale-up and the mass production. Moreover, development into printed electronics is possible, because the thin film can be formed easily employing a printing method, instead of a photoresist method which is generally used for patterning electrodes.

Furthermore, doping of N-type and P-type meeting the requirement is possible because acid treatment or the like is not conducted during the production of such an electrically conductive thin film. In fact, when doping was conducted, the reduction of the surface resistivity by one digit or more could be achieved.

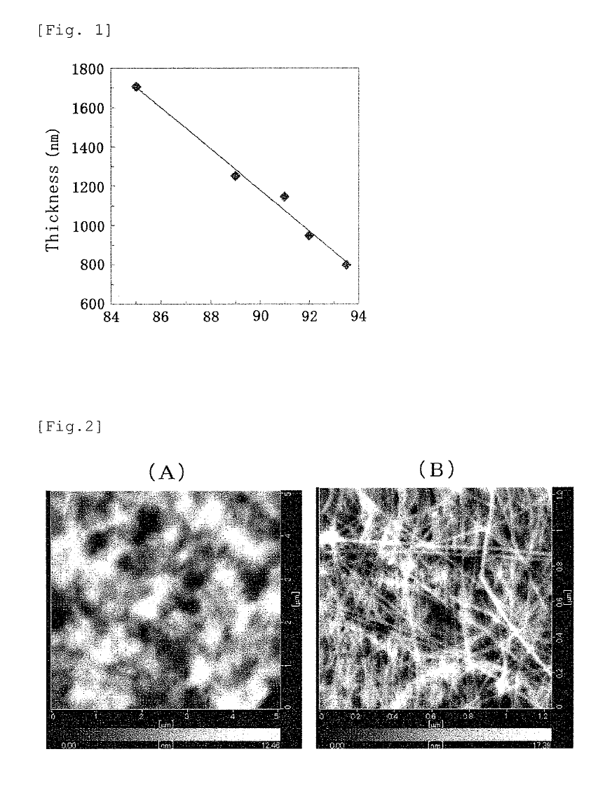

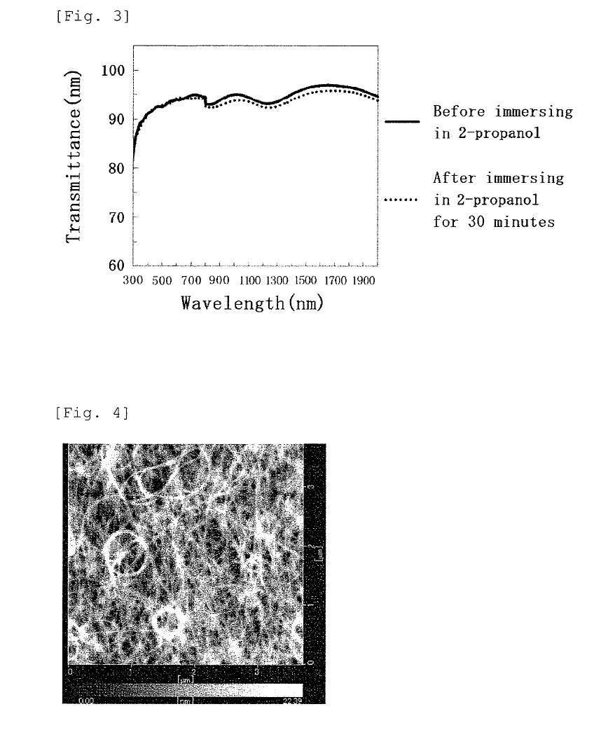

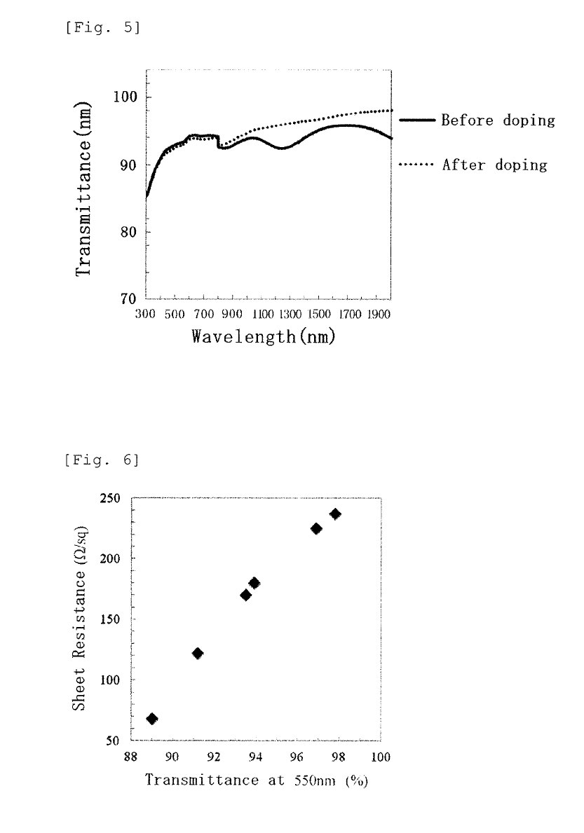

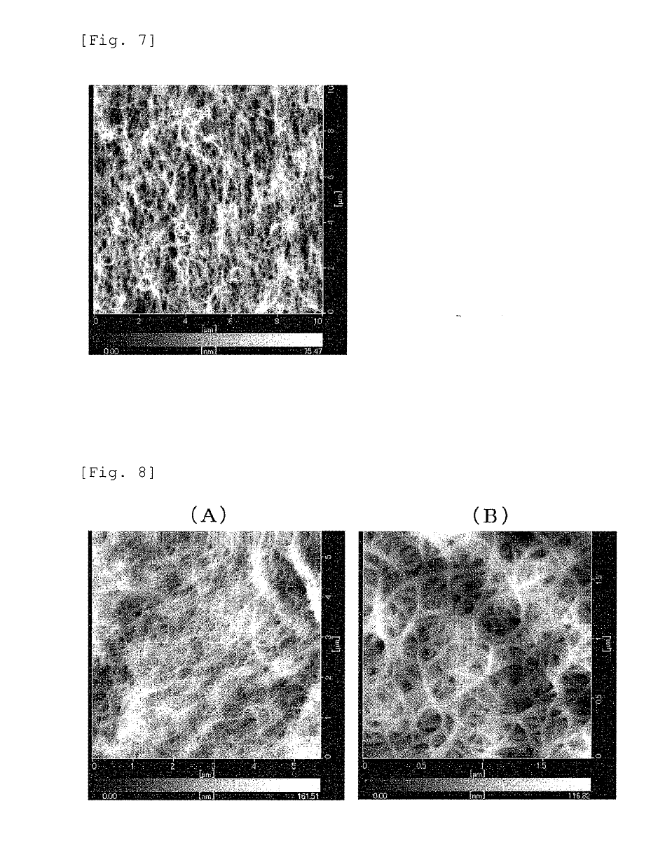

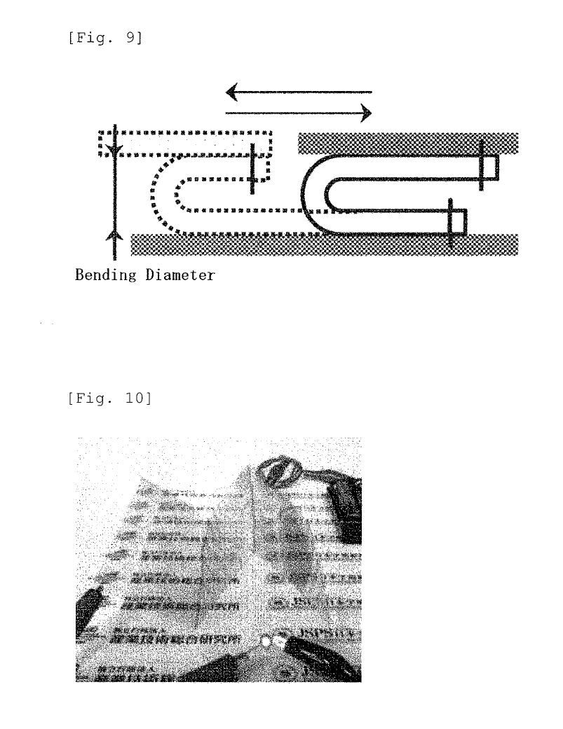

### BRIEF DESCRIPTION OF DRAWINGS

[FIG. 1] A figure showing the relationship between the thickness and the transmittance of the carbon nanotube-containing thin films obtained in Example 1

[FIG. 2] The atomic force microscope images of the carbon nanotube-containing thin film obtained in Example 2 before and after the immersion in 2-propanol

[FIG. 3] The ultraviolet-visible-near-infrared transmission spectra of the carbon nanotube-containing thin film obtained in Example 2 before and after the immersion in 2-propanol

[FIG. 4] The atomic force microscope image of the electrically conductive thin film obtained in Example 3

[FIG. 5] The ultraviolet-visible-near-infrared transmission spectra of the electrically conductive thin film obtained in Example 3

[FIG. 6] A figure showing the relationship between the transmittance and the sheet resistance of the electrically conductive thin films obtained in Example 3

[FIG. 7] The atomic force microscope image of the electrically conductive thin film obtained in Example 4

[FIG. 8] The atomic force microscope images of the electrically conductive thin film obtained in Example 5

[FIG. 9] A conceptual figure of the bendability test

[FIG. 10] A picture of a transparent electrically conductive film which was obtained by forming an electrically conductive thin film on a PEN substrate and was completely folded to make a mountain fold and a valley fold and in which both edges of the electrically conductive film were wired and connected to an LED lamp

### DESCRIPTION OF EMBODIMENTS

In the invention, the kind of the carbon nanotubes is not particularly limited and those which are conventionally known can be used. For example, single-wall carbon nanotubes, double-wall carbon nanotubes, multi-wall carbon nanotubes, carbon nanotubes having a rope shape or a ribbon shape can be all used. In addition, it is also possible to use single-type carbon nanotubes of metallic or semiconducting type which have been subjected to a separation step into metallic or semiconducting nanotubes.

In addition, when commercially available single-wall carbon nanotubes (SWNTs) are used, the carbon nanotubes are not particularly restricted by the length and the diameter, but those which have a diameter of 0.4 to 2.0 nm and a length of about 0.5 to 5.0 μm and are excellent in the crystallinity and long are preferable.

The type of the substrate is not particularly limited but a transparent substrate can be selected if necessary when a transparent electrically conductive thin film is formed. In addition to glass, quartz glass and the like, a flexible substrate and a transparent flexible substrate can be used. Specifically, substrates consisting of polyethylene naphthalate (PEN), polyimide (PI), polyethylene terephthalate (PET), polyethersulfone (PES), polyethylene (PE), polycarbonate (PC) and the like can be used, although the substrate is not limited to them.

The matrix polymer of the invention is preferably a cellulose derivative. For example, carboxymethyl cellulose, carboxyethyl cellulose, aminoethyl cellulose, oxyethyl cellulose, hydroxymethyl cellulose, hydroxyethyl cellulose, hydroxypropyl cellulose, methyl cellulose, ethyl cellulose, benzyl cellulose, trimethyl cellulose and the like are preferable.

In order to preferably produce the carbon nanotube-containing thin film of the invention, a solution of the cellulose derivative is first prepared and then the carbon nanotubes are added thereto and dispersed. As the solvent for the cellulose derivative, water, ethanol, chloroform, propylene glycol, a mixture of acetone and water and the like are preferably used. In this case, the concentration of the carbon nanotubes is 0.005 to 1% by weight, preferably 0.01 to 0.2% by weight, and the concentration of the cellulose derivative is 0.1 to 30% by weight, preferably 2 to 10% by weight . For dispersing the carbon nanotubes, it is possible to use means for accelerating the dispersion such as ultrasonic treatment in combination. The viscosity of the dispersion is appropriately determined in the range of 0.1 to 1,000 cps depending on the film-formation method. For example, the viscosity is preferably 6 to 10 cps in the case of film formation using a doctor blade and is preferably about 10 to 400 cps in the case of film formation by screen printing. These viscosities can be achieved by adjusting the molecular weight of the cellulose derivative.

It is preferable to subject thus obtained dispersion to centrifugal separation, collect the supernatant containing fine carbon nanotubes and use the supernatant as the carbon nanotube dispersion. In the centrifugal separation here, the rotation speed is 2,000 to 60,000 rpm, preferably 45,000 rpm and the centrifugal separation time is about two hours.

In this regard, these production conditions also show preferable ranges and it is needless to say that the conditions can be appropriately changed if necessary.

Thus obtained carbon nanotube dispersion contains the carbon nanotubes while the state of being separated from each other in the solution is maintained at a high concentration, due to the excellent dispersing effect of the cellulose derivatives such as hydroxypropyl cellulose.

The carbon nanotube-containing thin film of the invention can be obtained by forming a film of the carbon nanotube dispersion produced above on the substrate by a doctor blade method or a screen printing method. In this regard, the film-formation method is not limited to the doctor blade method and the screen printing method, and various film-formation methods such as a casting method, a dip coating method and a spin coating method can be employed. However, when a doctor blade method is employed, it is easy to adjust the thickness to provide films varying from one with a transmittance of 99% to an opaque film by changing the distance between the substrate and the blade and a thin film with a determined thickness can be uniformly formed even with a large area. In addition, patterning by a screen printing method is possible, because the viscosity can be adjusted appropriately without an additive, by adjusting the molecular weight of the cellulose derivative as the matrix polymer.

Next, the methods for removing the electrically-non-conductive matrix consisting of the cellulose derivative in the carbon nanotube-containing thin film are explained.

The first method is a method in which the carbon nanotube-containing thin film is immersed in a solvent to remove the electrically-non-conductive matrix, for example hydroxypropyl cellulose, and made into an electrically conductive thin film by thus recovering the electrical conductivity inherent in the carbon nanotubes.

The solvent is desirably a poor solvent relative to the material of the matrix. This is because the film disintegrates due to rapid dissolution in case of a good solvent with a high solubility. As the poor solvent, 2-propanol, tert-butyl alcohol, acetone, cyclohexanol, methyl ethyl ketone, methyl acetate, methylene chloride, butyl acetate, butyl cellosolve, lactic acid and the like can be used and xylene and 2-propanol (1:3) can be used as a mixed solution. The solvent is appropriately selected depending on the cellulose derivative, and for example, it is preferable to use 2-propanol when hydroxypropyl cellulose is used for the matrix.

It was confirmed that the matrix polymer was removed because the thickness of the electrically conductive thin film thus obtained reduced to about a tenth of the thickness before the immersion in the solution. After a large amount of the matrix polymer was removed, the sheet resistance became about several dozen to 2,000 Ω/sq from the state of a completely insulating film. When this thin film was further immersed in a concentrated nitric acid solution by a known method, the sheet resistance reduced to about a tenth by doping and an electrical conductivity sufficient for the use as a transparent electrode could be achieved.

The second method is a method in which the matrix polymer, for example hydroxypropyl cellulose, in the carbon nanotube-containing thin film obtained by the above method is removed by photonic curing and an electrically conductive thin film is obtained by thus recovering the electrical conductivity inherent in the carbon nanotubes. In this method, the carbon nanotubes generate heat by absorbing light and thus thermally decompose the surrounding matrix.

It is necessary that the light source can apply a light with an extremely high intensity in a very short time, and it is preferable to use a pulse laser, a xenon flash lamp or the like. For example, when the irradiation intensity is low, or the irradiation pulse is long resulting in a long irradiation, the influence of the dissipation of heat to the surrounding parts including the substrate becomes large. Thus, the heat generated in the carbon nanotubes cannot reach a temperature that is sufficiently high to thermally decompose the matrix or the substrate itself may be deformed or decomposed in case of a plastic substrate, and hence it is not appropriate as the process. By using the photonic curing apparatus used here which has a high intensity and in which the adjustment of the pulse time of several dozen to several thousand μs is easy, the surface of the material can be heated intensively. Thus, by significantly reducing the thermal influence on the substrate, as compared to the conventional heat sources, the photonic curing on a transparent flexible substrate has become possible.

For example, by applying a light with a pulse width of several hundred μs for several times on the carbon nanotube-containing thin film formed on a PEN substrate, it is possible to heat to the decomposition temperature of the carbon nanotubes (500° C.) or lower and decompose the matrix polymer around the nanotubes. On the other hand, the deformation and the decomposition of PEN as the substrate are not observed because the heat does not diffuse sufficiently with the light irradiation for a very short time.

After a large amount of the matrix polymer was removed, the sheet resistance of the electrically conductive thin film thus obtained became about several dozen to 2,000 Ω/sq from the state of a completely insulating film. When this thin film was further immersed in a concentrated nitric acid solution by a known method, the sheet resistance reduced to about a tenth by doping and an electrical conductivity sufficient for the use as a transparent electrode could be achieved.

The third method is a method in which the matrix, for example hydroxypropyl cellulose, in the carbon nanotube-containing thin film obtained by the above method is subjected to oxygen plasma and an electrically conductive thin film is obtained by thus recovering the electrical conductivity inherent in the carbon nanotubes. In this method, the surrounding matrix is oxidized and decomposed.

In the invention, by any of the first to third methods above, the electrically conductive thin film obtained can be doped by immersing in a concentrated nitric acid solution by a known method. It is known that the effect by this doping method usually reduces in about a week and the sheet resistance after the doping changes. However, in the electrically conductive thin film of the invention, the change in the sheet resistance is extremely small even several dozen days after the doping, as shown in the Examples below.

In the invention, it is also possible to combine at least two or more of the first to third methods above. For example, by the photonic curing method, although it is easy to remove the matrix polymer near the nanotubes, it is rather difficult to remove the polymer a little away from the nanotubes. This problem can be solved by combining the plasma method or the immersion method. In addition, when the immersion method is applied to a thin film with a low transmittance of 85% or less, that is, a relatively thick film or to a film with a large area, the film often peels from the substrate. In this case, by treating by the oxygen plasma method or the photonic curing method, the adherence of the film and the substrate is improved and thus the peeling from the substrate due to the immersion can be prevented.

In the invention, it is also possible to regulate the flexibility and the strength of the electrically conductive thin film, the adherence to the substrate and the like by leaving a part of the matrix, for example hydroxypropyl cellulose, which should be removed, in all of the first to third methods above.

Specifically, in case of the immersion method, when the carbon nanotube-containing thin film is immersed in the poor solvent, the matrix polymer is removed from the surface. For example, when the immersion time is adjusted short, the flexibility and the adherence of the electrically conductive film improve because a large amount of the polymer exists, while the strength and the electrical conductivity deteriorate. A condition suitable for the application should be found and controlled. In addition, in the photonic curing method, by adjusting the light intensity or the pulse width, the reaction area in the depth direction from the film surface is determined. Accordingly, by completely removing the matrix polymer at the film surface and leaving the matrix close to the substrate surface, the adherence to the substrate can be maintained. By employing this method, an electrically conductive thin film which is excellent in the flexibility and the adherence can be produced, while maintaining a high strength and a high electrical conductivity at the film surface.

Thus, the carbon nanotube-containing thin film in the invention can be formed as a uniform thin film easily by a solution process capable of forming the film at room temperature, without using a vacuum or high-temperature process, and the thickness can be adjusted. In addition, by removing the matrix from the carbon nanotube-containing thin film, the excellent electrical properties inherent in the carbon nanotubes can be exhibited sufficiently. Therefore, the thin film can be used advantageously as a transparent electrically conductive film, a transparent electrode, a flexible electrode, a semiconductor layer of a thin film transistor or the like. In addition, when the above photonic curing method is employed, by applying a light only to parts at which the electrical conductivity is required, an electrically conductive thin film with a pattern of electrical conductive parts can be also obtained.

In addition, in the invention, the electrically conductive thin film formed on the substrate is excellent in the stability at room temperature in the atmosphere, and the thin film is excellent in the bending resistance and is foldable owing to the bendability and the adherence specific to the carbon nanotubes. Thus, the thin film is useful as a flexible electrode in various applications such as a solar cell and an organic EL display as well as a touch screen.

### EXAMPLES

Next, the invention is described in further detail based on Examples. The explanations below are for easy understanding of the invention of this application and the invention is not limited to the explanations. That is, modifications, embodiments and other examples based on the technical idea of the invention of this application are all included in the invention of this application.

In this regard, in the following Examples, SWNTs synthesized by the direct injection pyrolytic synthesis (eDIPS) method of National Institute of Advanced Industrial Science and Technology were used.

First, the measurement methods and apparatuses used for the Examples are described.

### <Surface Resistance>

The surface resistivities of the carbon nanotube electrically conductive films were measured at room temperature in the atmosphere using 4-point probe method resistivity meter (Loresta, manufactured by Mitsubishi Chemical Corporation).

### <Thickness>

The thicknesses of the thin films produced were measured with Alphastep 500 (KLA-Tencor Corporation).

### <Ultraviolet-Visible-Near-Infrared Transmission Spectra>

The ultraviolet-visible-near-infrared transmission spectra were measured with Cary 500 (Varian, Inc).

### Example 1

Hydroxypropyl cellulose (HPC) in an amount of 2 g was dissolved in 40 ml of ethanol and 10 mg of SWNTs was then added thereto and mixed. The mixture was subjected to ultrasonic treatment to disperse the SWNTs and then subjected to centrifugal separation at a rotation speed of 45,000 rpm. The absorption spectrum and the luminescence spectrum of the supernatant after the centrifugal separation were measured, and it was confirmed that separated SWNTs were contained in the supernatant, referring to the data disclosed in NPL 1 (Science, 297, 593-596 (2002)).

A film of the dispersion solution was formed on a quartz glass substrate which was subjected to hydrophilization treatment, employing a doctor blade method, by moving a blade at a certain speed with an automatic apparatus. After leaving at room temperature for 10 minutes and drying the solvent a little, the film was completely dried with a hot plate (100° C.) and a carbon nanotube-containing thin film was obtained.

The thickness can be easily controlled by the distance between the substrate and the blade. In fact, by varying the distance between the substrate and the blade, optically uniform carbon nanotube-containing thin films with various thicknesses were obtained.

The correlation between the thickness and the transmittance is shown in FIG. 1. It is proven that the carbon nanotubes were uniformly dispersed in the thin films because the thickness and the transmittance had a nearly linear relationship as shown in the figure.

### Example 2

In this Example, hydroxypropyl cellulose as the matrix was removed by immersing a carbon nanotube-containing thin film obtained as in Example 1 above in 2-propanol.

Specifically, a quartz glass substrate on which a carbon nanotube-containing thin film with a transmittance at 550 nm of 93.5% and a thickness of 800 nm was formed and which was obtained as described above was immersed in 2-propanol for 30 minutes, taken out from 2-propanol and dried at 100° C. The thickness of the film obtained was about 80 nm and the transmittance at 550 nm scarcely changed. In addition, the sheet resistance measured nearly at the center of the obtained film was 1,500 Ω/sq.

The atomic force microscope images of the carbon nanotube-containing thin film before and after the immersion are shown in FIG. 2. In the figure, the image (A) is before the immersion and the image (B) is 30 minutes after the immersion.

As it is obvious from FIG. 2, each fiber of the carbon nanotubes can be observed clearly in the carbon nanotube-containing thin film after the immersion, and it was proven that the surrounding hydroxy cellulose was removed.

FIG. 3 shows the ultraviolet-visible-near-infrared transmission spectra of the carbon nanotube-containing thin film before and after the immersion. In this regard, step noises are seen in the region of 700 to 800 nm in the figure, and similar noises are seen also in FIG. 5 below. The noises are due to the changeover of the light-receiving part of the spectrometer.

As shown in FIG. 3, although the thickness reduced, the transmittance scarcely changed. Thus, it was proven that only hydroxypropyl cellulose, which is a transparent polymer, was efficiently removed by the immersion in 2-propanol and the carbon nanotubes remained on the substrate.

### Example 3

In this Example, doping was conducted by further immersing in concentrated nitric acid by a known method, as described below.

The substrate after removing the matrix polymer obtained in Example 2 was immersed in a nitric acid solution for 30 minutes to conduct doping. Then, excess nitric acid was removed with water and the substrate was dried with a hot plate at 50° C.

The atomic force microscope image of the film obtained in this Example is shown in FIG. 4 and the ultraviolet-visible-near-infrared transmission spectra of the film are shown in FIG. 5. As shown in FIG. 5, the absorption due to the semiconductor of the nanotubes disappeared, and it was confirmed that the nanotube film was doped with nitric acid ions. In addition, the sheet resistance measured nearly at the center of the film after the nitric acid treatment was about 170 Ω/sq, which is about a tenth of the value before the nitric acid treatment. This is an electrical conductivity sufficient for the use as an electrode.

In addition, carbon nanotube-containing thin films with various thicknesses which were each formed on a quartz glass substrate or a PEN substrate as in Example 1 were treated by methods similar to those in Example 2 and Example 3 to obtain electrically conductive thin films. The relationship between the transmittance and the sheet resistance of the electrically conductive thin films was examined. The relationship between the transmittance and the sheet resistance of the obtained electrically conductive thin films is shown in FIG. 6.

As shown in FIG. 6, electrically conductive thin films with various transmittances and sheet resistances can be individually produced by adjusting the film-formation condition.

### Example 4

In this Example, a carbon nanotube-containing thin film which was formed on a PEN substrate as in Example 1 was subjected to oxygen plasma treatment and hydroxypropyl cellulose as the matrix was removed.

The oxygen plasma treatment was conducted at 80 W for five minutes using Atmospheric Process Plasma (A•P•P Co., LTD) atmospheric pressure plasma apparatus. The sheet resistance achieved was 10⁷ Ω/sq. The atomic force microscope image of the film obtained in this Example is shown in FIG. 7.

Although the film obtained in this Example still had a high sheet resistance, each nanotube can be observed clearly due to the removal of the matrix polymer, as shown in FIG. 7.

### Example 5

In this Example, a carbon nanotube-containing thin film which was obtained as in Example 1 above was irradiated with a light and hydroxypropyl cellulose as the matrix was removed.

The photonic curing was conducted at room temperature in the atmosphere using a xenon flash lamp (NovaCentrix, PulseForge).

A white pulse light of 330 microseconds was applied to the carbon nanotube-containing thin film formed on a PEN substrate at room temperature in the atmosphere for three times. The sheet resistance was 130 Ω/sq. This is an electrical conductivity sufficient for the use as an electrode.

The atomic force microscope images of the carbon nanotube-containing thin film after the photonic curing are shown in FIG. 8. In this regard, the image (B) is a partial enlargement of the image (A).

As shown in FIG. 8, each carbon nanotube fiber can be observed clearly and it was proven that hydroxypropyl cellulose surrounding the carbon nanotubes was removed by the photonic curing. In particular, it can be seen that the matrix polymer around the nanotubes was completely removed because this removal method uses the heat generated in the carbon nanotubes. In addition, by adjusting the pulse width of the light, deformation of the PEN substrate or the like was not observed at all.

### Example 6

In case of a thick film with a transmittance of 80% or less or a film with a large area, the film peels from the substrate when it is immersed in a solvent and thus a preferable electrically conductive thin film cannot be obtained. Thus, in this Example, carbon nanotube-containing thin films having transmittances of 70% and 77% each formed on a PEN substrate were irradiated with a white pulse light of 300 microseconds for five times, four times or once to conduct the photonic curing. After immersing in 2-propanol for 30 minutes, the films did not peel off and electrically conductive thin films with sheet resistances of 140 Ω/sq, 118 Ω/sq and 210 Ω/sq could be obtained.

When the thin films were further treated with nitric acid, electrically conductive films with very high sheet resistances, namely 37 Ω/sq, 30 Ω/sq and 37 Ω/sq, could be obtained.

Table 1 below is a summary of the above results.

TABLE 1

| Transmittance | Light Irradiation | 2- Propanol | HNO₃ |
|---|---|---|---|
| 70 | 300 Ω/sq (5 Times) | 140 Ω/sq | 37 Ω/sq |
| 77 | 220 Ω/sq (4 Times) | 118 Ω/sq | 30 Ω/sq |
| 70 | 940 Ω/sq (1 Time) | 210 Ω/sq | 37 Ω/sq |

### Example 7

In this Example, a bendability test was conducted using electrically conductive thin films which were each formed on a PEN substrate by the method of Example 6.

The bendability test was conducted at room temperature in the atmosphere using FPC (flexible print circuit) flexing tester (Yasuda Seiki Seisakusho, LTD.). FIG. 9 is a conceptual figure of the bendability test. A sample fragment is fixed with a determined bending radius between a fixing plate and a movable plate, which are parallel to each other, and the movable plate is moved from side to side to conduct the bendability test.

In this Example, a PEN substrate on which an electrically conductive thin film was formed was fixed with a determined bending radius between a fixing plate and a movable plate, which were parallel to each other, and the movable plate was moved from side to side to conduct the bendability test. The speed was set at 70.5 cpm, which was the fastest among the 10 scales, and the bending diameter was set at 20 mm or 4 mm.

As a result, it was confirmed that, in case of the bending diameter of 20 mm, the electrical conductivity was maintained until 200,000 times. Although the measurement was not conducted after this, the property was still maintained sufficiently. In addition, in case of the bending diameter of 4 mm, no damage to the electrically conductive thin film was observed until 50,000 times. However, the PEN substrate broke first at around 53,000 times, and the test could not be continued further. This is not due to the actual influence of bending of the carbon nanotube electrically conductive thin film on the electrical conductivity, but a problem of the thickness of PEN as the substrate. By using a thinner PEN substrate, the property can be exhibited even with a smaller bending diameter.

As described above, the electrically conductive thin film of the invention is excellent in the bending resistance. Thus, when the electrically conductive thin film of the invention is formed on a flexible substrate and a touch screen is produced, the touch screen can be operated in a warped state.

### Example 8

In this Example, a transparent electrically conductive film obtained by forming an electrically conductive thin film on a PEN substrate as in Example 6 was completely folded to make a mountain fold and a valley fold and then both edges of the electrically conductive film were wired and connected to an LED lamp. As a result, it can be seen that the LED was on although the film was completely folded, as shown in FIG. 10. This is due to the specific bendability and adherence of the carbon nanotubes and an electric current could flow due to the excellent bending resistance and impact resistance, even when the film was folded.

### Example 9

In this Example, two electrically conductive thin films (1 and 2) having different thicknesses and areas which were each formed on a PEN substrate by a method similar to that of Example 3 were obtained. The sheet resistances of the films were measured from the day on which the electrically conductive thin films were produced, to the 120th day for the thin film 1, and to the 90th day for the thin film 2, and the changes in the sheet resistance with the time were observed.

The results are shown in Table 2. In this regard, in the table, the largest value and the smallest value of the values measured nearly at the center and at surrounding four points per sheet are shown because the thin film 1 was large; while the value measured nearly at the center is shown for the thin film 2 because the thin film 2 was small.

As shown in Table 2 below, it was found that the changes in the sheet resistance were extremely small even several dozen days after the production.

TABLE 2
Ω/□

| | Day of | | | | | | | | | |
|---|---|---|---|---|---|---|---|---|---|---|
| | Production | 2nd Day | 3rd Day | 5th Day | 6th Day | 8th Day | 14th Day | 30th Day | 90th Day | 120th Day |
| Thin film 1 | 60-200 | 60-200 | | 70-200 | 65-190 | 70-170 | 74-130 | 78-160 | | 80-160 |
| Thin film 2 | 400 | | 400 | 380 | | | 410 | | 412 | |

### INDUSTRIAL APPLICABILITY

The carbon nanotube-containing thin film of the invention can be formed easily by a doctor blade method, a screen printing method or the like with carbon nanotubes existing in a uniformly dispersed state, and the thickness and the light transmittance of the film can be adjusted easily. By removing the matrix from the carbon nanotube-containing thin film, the high electrical conductivity or the high semiconductor properties inherent in carbon nanotubes and the excellent bendability can be sufficiently exhibited. Thus, the thin film is extremely useful as a transparent electrode and a flexible electrode.

1. A method for producing an electrically conductive thin film by removing an electrically-non-conductive matrix consisting of a cellulose derivative from a carbon nanotube-containing thin film in which carbon nanotubes are dispersed in a state of being separated from each other in the electrically-non-conductive matrix,
wherein the electrically-non-conductive matrix is removed by treating the carbon nanotube-containing thin film with a poor solvent.

2. A method for producing an electrically conductive thin film, wherein the poor solvent is 2-propanol.

3. A method for producing an electrically conductive thin film by removing an electrically-non-conductive matrix consisting of a cellulose derivative from a carbon nanotube-containing thin film in which carbon nanotubes are dispersed in a state of being separated from each other in the electrically-non-conductive matrix,
wherein the electrically-non-conductive matrix is removed by photonically curing the carbon nanotube-containing thin film.

4. A method for producing an electrically conductive thin film by removing an electrically-non-conductive matrix consisting of a cellulose derivative from a carbon nanotube-containing thin film in which carbon nanotubes are dispersed in a state of being separated from each other in the electrically-non-conductive matrix,
wherein the electrically-non-conductive matrix is decomposed and removed by applying oxygen plasma to the carbon nanotube-containing thin film.

5. The method for producing an electrically conductive thin film according to claim 1, wherein the cellulose derivative is hydroxypropyl cellulose.

6. The method for producing an electrically conductive thin film according to claim 1, wherein two or more of the methods described in claims 1, 3 and 4 are combined.

7. The method for producing an electrically conductive thin film according to claim 1, wherein the electrically-non-conductive matrix is removed from the carbon nanotube-containing thin film except for a part thereof.

8. The method for producing an electrically conductive thin film according to claim 1, wherein the carbon nanotube-containing thin film is a thin film formed by a doctor blade method or a screen printing method.

9. An electrically conductive thin film which is produced by the method described in claim 1.

10. The electrically conductive thin film according to claim 9 which is formed on a substrate consisting of a plastic film having a softening point or a decomposition point lower than 300° C.

11. A transparent electrode which has the electrically conductive thin film according to claim 9 on a transparent substrate.

12. The transparent electrode according to claim 11, wherein the transparent substrate is a plastic film having a softening point or a decomposition point lower than 300° C.
